(19) United States
(12) Patent Application Publication
(10) Pub. No.: US 2006/0042546 A1
(43) Pub. Date: Mar. 2, 2006

(54) Plasma processing apparatus and controlling method therefor

(75) Inventors: Nobuo Ishii, Hyogo (JP); Kibatsu Shinohara, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: TOKYO ELECTRON LIMITED

(21) Appl. No.: 10/519,775

(22) PCT Filed: Jul. 24, 2003
(86) PCT No.: PCT/JP03/09404

§ 371 Date: Dec. 29, 2004

(30) Foreign Application Priority Data
Jul. 24, 2002 (JP) 2002-215503

(51) Int. Cl. C23C 16/00

(52) U.S. Cl. 118/723 MW

(57) ABSTRACT

A detector detects microwaves reflected from a processing chamber. Based on the reflected microwaves, a load impedance is calculated. An amount of adjustment required to match the load impedance with an impedance of a microwave oscillator is calculated. The calculated amount of adjustment multiplied by a predetermined value smaller than 1 is transmitted as an adjustment signal. A load matching device is repeatedly controlled based on the adjustment signal. Consequently, the load impedance gradually approaches the impedance of the oscillator. Eventually, an impedance match is attained.

### BACKGROUND OF THE INVENTION

1. Field of the Invention

The present invention relates to a plasma processing apparatus for use in fabricating a semiconductor or a liquid crystal display panel, and a control method for the plasma processing apparatus. More particularly, the present invention is concerned with a microwave plasma processing apparatus capable of efficiently transmitting energy, which is generated by a microwave oscillator, to the load, a plasma, in a vacuum chamber.

2. Description of the Related Art

For a semiconductor fabricating process, a plasma processing apparatus is used to perform physical vapor deposition (PVD), chemical vapor deposition (CVD), or the like so as to form a thin film on a wafer.

The plasma processing apparatus is available in various types. In a widely adopted microwave plasma processing apparatus, microwaves are introduced from a microwave oscillator such as a magnetron into an antenna via a waveguide, and then radiated from the antenna to a vacuum chamber. Gaseous molecules are then excited by the microwaves to form a thin film on the surface of a wafer.

In the microwave plasma processing apparatus, it is most important, in terms of effective energy use and provision of high-quality products, to efficiently introduce the microwaves generated by the microwave oscillator into the plasma in the vacuum chamber and to keep the electric field in the vacuum chamber uniform (Japanese Unexamined Patent Application Publication No. 2002-50613).

In order to efficiently supply the energy which is generated by the microwave oscillator to the plasma, a load impedance viewed from the oscillator, that is, an equivalent impedance occurring in the plasma must match an oscillator impedance viewed from the load. Consequently, a load matching device is interposed between the oscillator and the antenna in order to regulate the load impedance so that the load impedance will match the oscillator impedance.

However, the equivalent impedance in the plasma varies nonlinearly, depending on the density of plasma, and it is not easy to adjust the load matching device.

### SUMMARY OF THE INVENTION

The present invention attempts to solve the foregoing problem. An object of the present invention is to provide a plasma processing apparatus and control method for the plasma processing apparatus capable of efficiently conveying energy, which is generated by a microwave oscillator, to the load gas in a vacuum chamber.

The present invention provides a plasma processing apparatus that utilizes microwaves to generate plasma, comprising a load matching device capable of adjusting an impedance and a wave detector which detects microwaves reflected from a processing chamber. The load matching device is stepwise controlled to match an impedance of the processing chamber, which is calculated based on the microwaves detected by the wave detector with an impedance of a microwave oscillator.

According to the present invention, an impedance match is reliably attained and energy generated by the microwave oscillator can be efficiently transferred to the processing chamber.

Moreover, according to the present invention, an amount of adjustment to which the load matching device must be adjusted in order to match the impedance of the processing chamber with the impedance of the microwave oscillator is calculated. The calculated amount of adjustment multiplied by a predetermined value smaller than 1 is transmitted as an adjustment signal. The load matching device is repeatedly stepwise controlled according to the adjustment signal until the impedance of the processing chamber matches the impedance of the microwave oscillator.

The predetermined value may be variable. When the amount of adjustment is large, the value may be large. When the amount of adjustment is small, the multiple may be small. Thus, even when the load impedance varies due to a change in the state of the plasma, an impedance match can be reliably attained.

Furthermore, according to the present invention, when no plasma is generated in the processing chamber, the calculated adjustment amount may be transmitted as the adjustment signal as it is. When plasma is generated, the adjustment amount multiplied by a predetermined value smaller than 1 may be transmitted as the adjustment signal.

Before plasma is generated, an impedance match can be attained more quickly than after plasma is generated.

### BRIEF DESCRIPTION OF THE DRAWINGS

The present invention will be described with reference to the following drawings:

FIG. 1 is a sectional view of a plasma processing apparatus in which the present invention is implemented;

FIG. 2 is a graph indicating the relationship between a density of plasma nₑ and a dielectric constant εₚ thereof;

FIG. 3 shows a first structure of a circular waveguide including a load matching device and a wave detector;

FIG. 4 is a conceptual diagram of stub adjustment;

FIG. 5 shows the configuration of a first load matching device controller;

FIG. 6 is a flowchart describing a load matching device control routine;

FIG. 7 shows the configuration of a second load matching device controller; and

FIG. 8 shows a second structure of the circular waveguide including the load matching device and wave detector.

### DESCRIPTION OF THE PREFERRED EMBODIMENTS

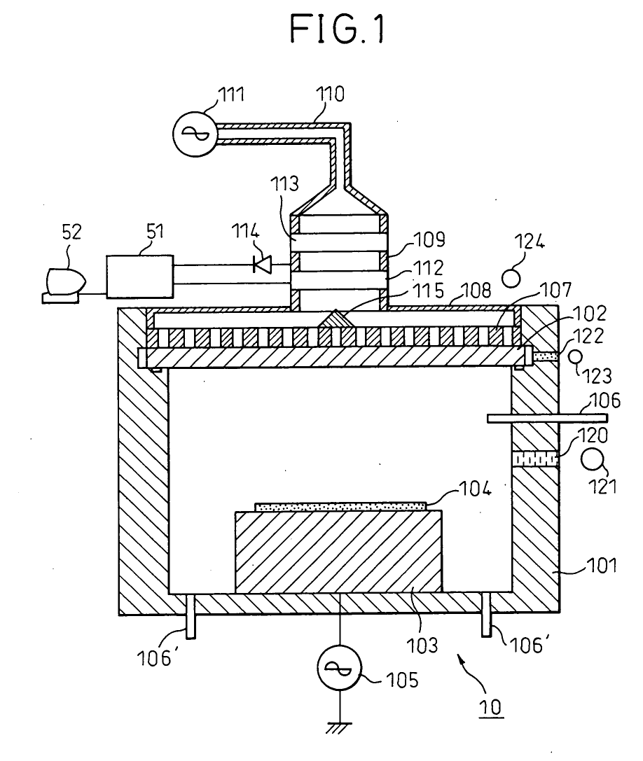

FIG. 1 is a sectional view of a plasma processing apparatus in which the present invention is implemented. A processing chamber 10 comprises a bottomed cylindrical container 101 and a quartz plate 102 serving as the lid of the bottomed cylindrical container 101.

A placement base 103 is put in the processing chamber 10, and a wafer 104 that is an object for plasma processing is loaded on the placement base 103. An electrostatic chuck may be installed in the placement base 103 in order to fix the wafer 104 to the placement base 103. A high-frequency bias power supply 105 is connected to the placement base 103.

A gas supply pipe 106 through which gas is supplied to the processing chamber 10 is embedded in the wall of the processing chamber 10, and exhaust pipes 106′ through which gas is discharged are embedded in the bottom thereof.

A flat-plate slot antenna 107 is mounted on the quartz plate 102, and covered with a disk-like radial waveguide box 108.

A circular waveguide 109 is mounted in the center of the radial waveguide box 108, and connected to a microwave oscillator 111 via a rectangular waveguide 110.

A load matching device 112 is inserted into part of the radial waveguide 109 located near the radial waveguide box 108, and a circularly polarized wave converter 113 is inserted into the other part of the radial waveguide 109 located near the rectangular waveguide 110. Moreover, a wave detector 114 is arranged between the load matching device 112 and the circularly polarized wave converter 113.

Furthermore, for example, a conical metal bump 115 is formed in the center of the flat-plate slot antenna 107 in order to uniformly distribute microwaves.

After the bottomed cylindrical container 101 is covered with the quartz plate 102 and brought to a vacuum, a gas is introduced into the container through the gas supply pipe 106. When microwaves are radiated through the flat-plate slot antenna 107, the gaseous molecules are ionized to make a plasma.

The dielectric constant εₚ of the plasma is expressed as equation (1).
εₚ=1−ω_{c}²/ω² (1)
where ω_{c} denotes an natural angular frequency of plasma, and a denotes an oscillatory angular frequency of the microwave oscillator.

Since the square of the angular frequency of plasma ω_{c} is proportional to the density of plasma nₑ, the following equation (2) is established:
ω_{c}²αn (2)
where nₑ denotes the density of plasma.

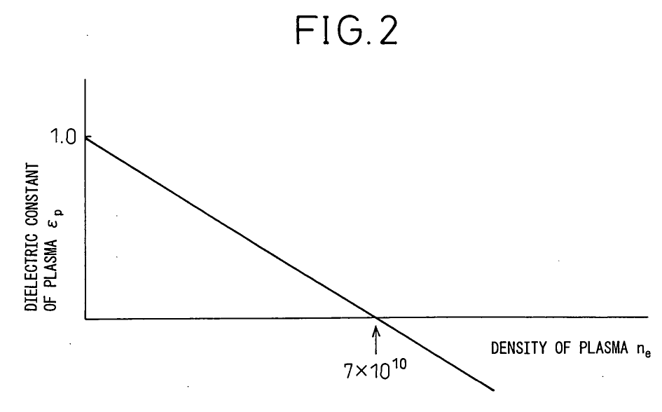

FIG. 2 is a graph approximately indicating the relationship between the density of plasma nₑ and the dielectric constant thereof εₚ. When the oscillatory frequency at which the microwave oscillator oscillates is 2.45 GHz, if the density of plasma nₑ is approximately 7×10¹⁰ per 1 cm³, the angular frequency of plasma ω_{c} becomes equal to the oscillatory angular frequency of the microwave oscillator 111 to make the dielectric constant of plasma εₚ zero. Moreover, the equivalent impedance Zₚ in the plasma is broadly proportional to the dielectric constant of plasma εₚ raised to the power of −½, the following equation (3) is established:

$${Z}_{P} {αɛ}_{P}^{- \frac{1}{2}} = 1 \text{/} \sqrt{{ɛ}_{P}} \qquad ( 3 )$$

Based on equations (1) to (3), equation (4) is obtained.

$${Z}_{P} = {\{ 1 - k ( \frac{{n}_{e}}{{ω}^{2}} ) \}}^{- \frac{1}{2}} \qquad ( 4 )$$

where k denotes a constant of proportion, nₑ denotes the density of plasma, and ω denotes the oscillatory frequency of the microwave oscillator.

As mentioned above, the equivalent impedance Zₚ of plasma is a function of the density of plasma nₑ. If the load matching device is adjusted to an amount calculated based on the impedance of the processing chamber in order to match the impedance of the processing chamber, including the equivalent impedance in plasma with the impedance of the microwave oscillator, the state of the plasma in the processing chamber is changed to vary equivalent impedance in plasma. The amount of adjustment of the load matching device must be modified again.

Moreover, the equivalent impedance in plasma in the processing chamber is expressed as a non-linear function of the density of plasma by the equation (4). There may be therefore a difficulty in realizing an impedance match by only once manipulating the load matching device.

According to the present invention, the wave detector 114 and load matching device 112 are coupled to each other via a controller in order to gradually achieve an impedance match.

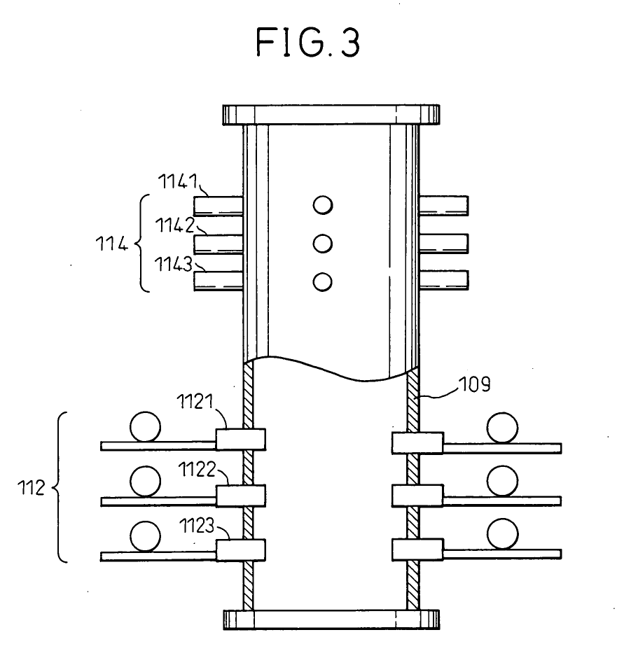

FIG. 3 is a diagram showing a first structure of a circular waveguide that includes the load matching device and wave detector. The load matching device 112 is of a stub type. Four sets of stubs 112 are circumferentially arranged at intervals of 90° on the circular waveguide 109. Each set of stubs comprises three stubs 1121, 1122, and 1123 disposed with a space, which is equivalent to a quarter of the internal wavelength of microwaves axially propagated through the circular waveguide 109, between adjoining stubs.

The stubs belonging to each set of stubs can be radially inserted into or pulled out of the circular waveguide 109 owing to a actuating mechanism composed of, for example, a pulse motor and a rack and pinion.

Adjustment of insertion amounts x₁, x₂ and x₃, to which the stubs 1121, 1122 and 1123 are inserted into the circular waveguide 109, can change the ratio at which microwaves reflecting or returning from the load, i.e., the processing container 101 are reflected again by stubs to the load. Accordingly, the impedance of the load can be adjusted.

The wave detector 114 is disposed on the upstream side of the circular waveguide 109 beyond the load matching device 112. The wave detector 114 comprises, similarly to the load matching device 112, four sets of wave detection elements circumferentially disposed at intervals of 90° on the circular waveguide 109 or two sets of wave detection elements separated by 90° from each other thereon. Each set of wave detection elements comprises three wave detection elements 1141, 1142, and 1143 that are disposed with a space, which is equivalent to a ⅛ of the internal wavelength λ_{g} of microwaves that are axially propagated through the circular waveguide 109, between adjoining wave detection elements.

If voltages detected by the three wave detection elements 1141, 1142, and 1143 are v₁, v₂, and v₃, the following equation (5) are obtained:
v₁=k|vᵢ|²(1+Γ²+2|Γ| cos θ)
v₂=k|vᵢ|²(1+Γ²−2|Γ| sin θ) (5)
v₃=k4|vᵢ|²(1+Γ²−2|Γ| cos θ)
where vᵢ denotes an output voltage of the microwave oscillator, Γ denotes a reflection coefficient, and θ denotes a phase.

Consequently, once the three wave detection elements 1141, 1142, and 1143 detect the wave-detection voltages v₁, v₂, and v₃, the reflection coefficient Γ and phase θ can be calculated.

As the reactances offered by the stubs 1121, 1122, and 1123 are calculated based on the reflection coefficient Γ, phase θ, and the positions of the stubs, the impedance of the load can be calculated.

The amounts of insertion to which the stubs should be inserted in order to match the impedance of the load with the impedance of the microwave oscillator are calculated, and the deviations of the calculated amounts from the current amounts of insertion are calculated. Based on the deviations, the stubs are manipulated.

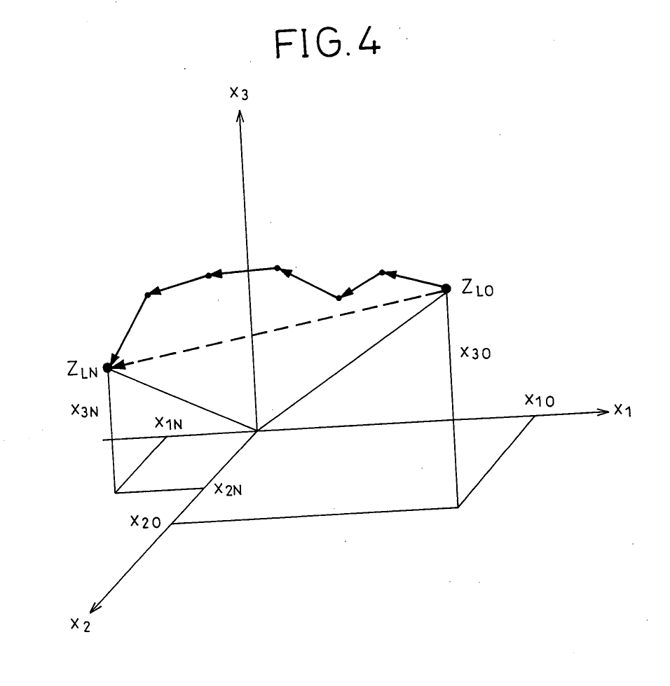

FIG. 4 is a conceptual diagram of stub adjustment. The amounts of stub insertion x₁, x₂ and x₃ are indicated with the coordinate axes of the right-hand system in the three-dimensional space.

An impedance Z_{L} of the processing chamber viewed from the wave detector is expressed with equation (6) as a function of not only the dielectric constant of plasma εₚ but also the amounts of stub insertion x₁, x₂ and x₃.
Z_{L}=Z_{L}(x₁, x₂, x₃, εₚ) (6)

Namely, stub adjustment can be regarded as an operation for moving a vector, which is represented with coordinates (x₁₀, x₂₀, and x₃₀) in the three-dimensional space and which expresses an impedance Z_{L0} of the processing chamber viewed from the wave detector, into another vector that is represented with coordinates (x_{1N}, x_{2N}, and x_{3N}) and that expresses a matched impedance Z_{LN}.

If the coordinates (x₁₀, x₂₀, and x₃₀) of the vector and (x_{1N}, x_{2N}, and x_{3N}) of the other vector are known, an operation vector whose initial point corresponds to the one point expressing the impedance Z_{L0} and whose terminal point corresponds to the other point expressing the matched impedance Z_{LN} is determined uniquely.

However, as mentioned previously, the impedance Z_{L} of the processing chamber viewed from the wave detector is a function of the dielectric constant of plasma εₚ. Therefore, if the initial point represented with (x₁₀, x₂₀, and x₃₀) is, as indicated with a dashed line, directly shifted to the terminal point (x_{1N}, x_{2N}, and x_{3N}), the dielectric constant of plasma εₚ varies during the shift. This causes the impedance Z_{L} of the processing chamber to change. An impedance match is not assured.

According to the present invention, as indicated with a solid line, while the load impedance is being monitored, the amounts of stub insertion are adjusted little by little in order to finally attain an impedance match.

In other words, the operation vector whose initial point is represented with coordinates (x₁₀, x₂₀, and x₃₀) and whose terminal point is represented with coordinates (x_{1N}, x_{2N}, and x_{3N}) is calculated. The initial point expressing the load impedance Z_{L0} is shifted by the quantity of the calculated vector multiplied by a predetermined value smaller than 1.

Thereafter, the above procedure is repeated with the shifted initial point expressing the load impedance as a new initial point. Finally, an impedance match is attained.

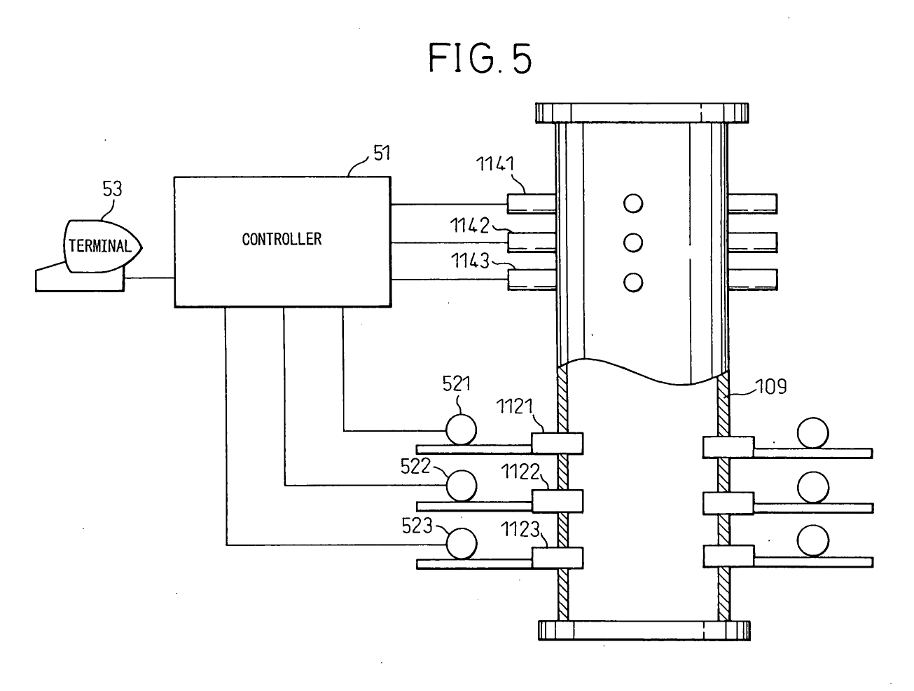

FIG. 5 shows the configuration of a first load matching device controller employed in a plasma processing apparatus in accordance with the present invention. Outputs of the wave detection elements 1141, 1142, and 1143 are input into a controller 51. Moreover, actuators 521, 522, and 523 for adjusting the amounts of insertion of the stubs 1121, 1122, and 1123 are driven with a manipulation signal transmitted from the controller 51.

The controller 51 is realized with, for example, a microcomputer system and operated at a terminal 53.

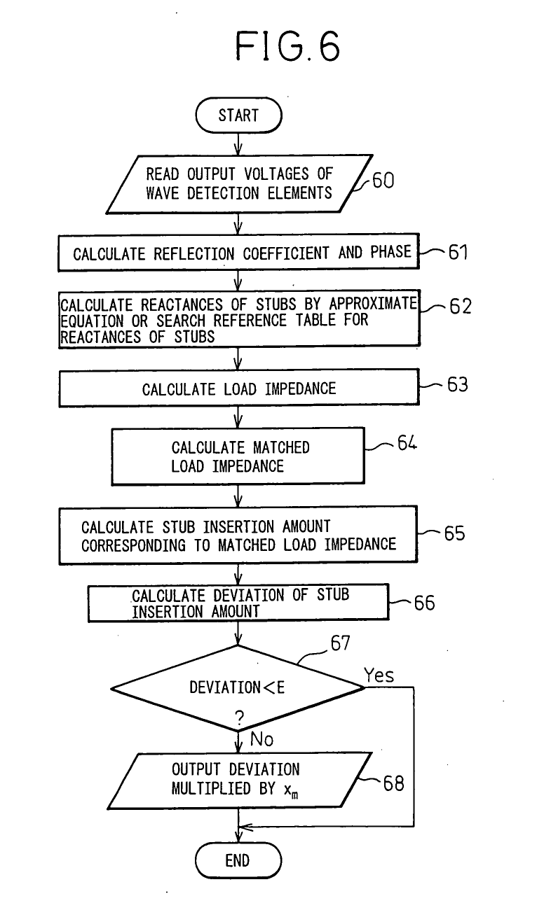

FIG. 6 is a flowchart describing a load matching device control routine to be controlled by the controller 51. The routine is started by an interrupt at regular intervals.

First, at step 60, the output voltages v₁, v₂ and v₃ of the three wave detection elements 1141, 1142, and 1143 included in the wave detector 114 are read. At step 61, a reflection coefficient Γ and phase difference θ are calculated according to the equation (4).

At step 62, the reactances of the stubs 1121, 1122, and 1123 are calculated based on the positions thereof.

At step 63, the reflection coefficient Γ and phase difference θ are used to calculate a load impedance viewed from the wave detector 114, that is, a combined impedance offered by the plasma in the processing container 101, the flat-plate slot antenna 107, radial waveguide 108, and load matching device 112 in consideration of the fact that the three stubs 1121, 1122, and 1123 are arranged with a space, which is equivalent to a quarter of the wavelength of microwaves, between adjoining stubs.

At step 64, a matched load impedance Z_{LN} to match an impedance Zₛ of the microwave oscillator 111 viewed from the wave detector 114 is calculated. At step 65, the amount of matched stub-insertion required to realize the matched load impedance Z_{LN} are calculated.

At step 66, the deviations (Δx₁, Δx₂, and Δx₃) that are the differences between the current amounts of stub insertion (x_{1N}, x_{2N}, and x_{3N}) and the amounts of matched stub insertion (x_{1N}, x_{2N}, and x_{3N}) required to match the load impedance with the impedance of the microwave oscillator are calculated.

At step 67, the deviations (Δx₁, Δx₂, Δx₃) of the amount of stub insertion are checked to see if they are smaller than a predetermined threshold E.

If the check performed at step 67 is negative, that is, if the deviations (Δx₁, Δx₂, and Δx₃) are equal to or larger than the predefined threshold E, the deviations (Δx₁, Δx₂, and Δx₃) multiplied by m (where m<1.0, for example, 0.5) are transmitted as manipulation signals. The routine is then terminated. The pulse motors 521, 522, and 523 are rotated based on the manipulation signals, whereby the amount of insertion of the stubs 1121, 1122, and 1123 are adjusted.

In contrast, if the check at step 67 is affirmative, that is, if the deviations (Δx₁, Δx₂, and Δx₃) are smaller than the predefined threshold E, an impedance match is thought to be attained. No manipulation signals are transmitted, and the routine is directly terminated. In this case, the amounts of stub insertion remain unchanged and the impedance match is maintained.

According to the foregoing method, an impedance match can be reliably attained. However, before plasma is generated in the processing container 101, the amounts of stub insertion are limited and it takes much time to attain the impedance match, even though the load impedance is held nearly constant.

Therefore, before plasma is generated, m may be set to 1.0 in order to increase the degrees of stub insertion. Thus, the time elapsing until an impedance match is attained is shortened. After plasma is generated, m may be set to a value smaller than 1.0 so that the impedance match can be reliably attained.

The generation of plasma can be checked by detecting light, which is emitted in the plasma and passes through a window 120 (FIG. 1), using a photoelectric element 121. The window 120 is formed with a quartz glass plate mounted in the wall of the processing container. Specifically, when the photoelectric element 121 does not detect the light emitted in the plasma, m is set to 1.0. When the photoelectric element 121 detects the light emitted in the plasma, m is set to the value smaller than 1.0.

The controller has all the capabilities thereof realized with one microcomputer. Therefore, unless the interval between executions of the load matching device control routine is reduced to some extent, the time to realize an impedance match gets longer.

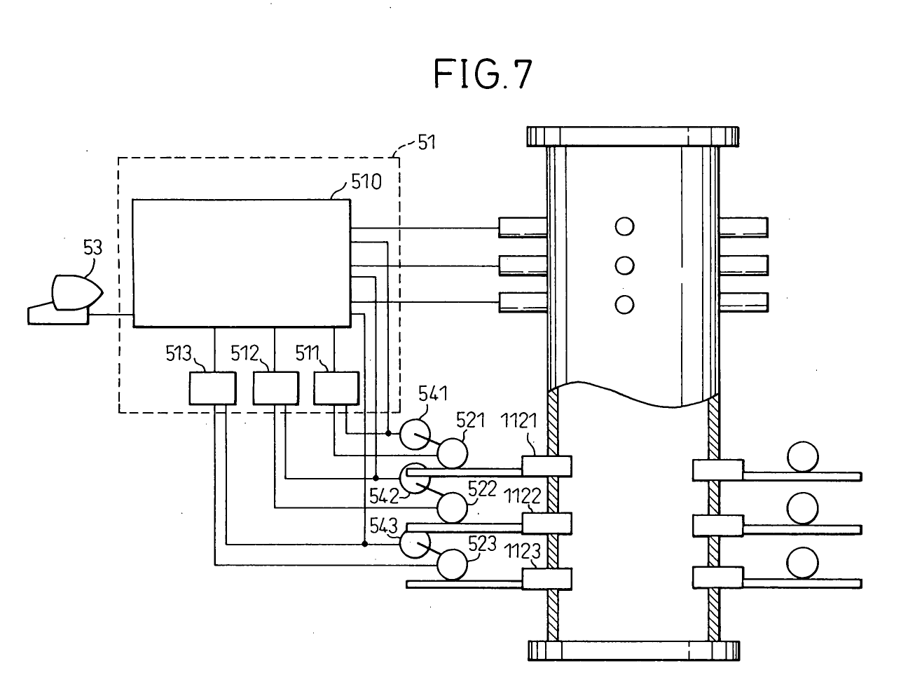

FIG. 7 shows the structure of a second load matching device controller employed in a plasma processing apparatus in accordance with the present invention. In order to solve the foregoing problem, the controller has a hierarchy.

Specifically, the controller 51 comprises an operational unit 510, and three position control units 511, 512, and 513.

Furthermore, rotary encoders 541, 542, and 543 are directly coupled to three pulse motors 521, 522, and 523 that adjust the amounts of insertion of the stubs 1121, 1122, and 1123.

The amounts of insertion of the stubs, which are detected by the rotary encoders 541, 542, and 543, are fed back to the associated position control units 511, 512, and 513, and also fetched into the operational unit 510.

According to the present configuration, the operational unit 510 executes the steps 60 to 67 included in the load matching device control routine, and transmits manipulation commands, which are concerned with the three stubs 1121, 1122, and 1123, to the respective position control units 511, 512, and 513.

The position control units 511, 512, and 513 control the amount of stub insertion on the basis of the manipulation commands and the amount of insertion to which the stubs are actually inserted and which are detected by the rotary encoders 541, 542, and 543.

According to the present configuration, the arithmetic unit 510 need not wait until the pulse motors stop acting but can concentrate on calculation of the desired amount of insertion to which the stubs should be inserted. The position control units 511, 512, and 513 can concentrate on controlling of the amount of insertion of the stubs.

Thus, if the deviations are large, the rotating speeds of the motors are increased. If the deviations are small, the rotating speeds of the motors are decreased. Consequently, the moving speeds of the stubs can be increased. Eventually, the time interval for matching the load impedance with the impedance of the microwave oscillator can be reduced.

Furthermore, according to the present embodiment, the load matching device is structured using the stubs. Alternatively, the load matching device may be of any other type.

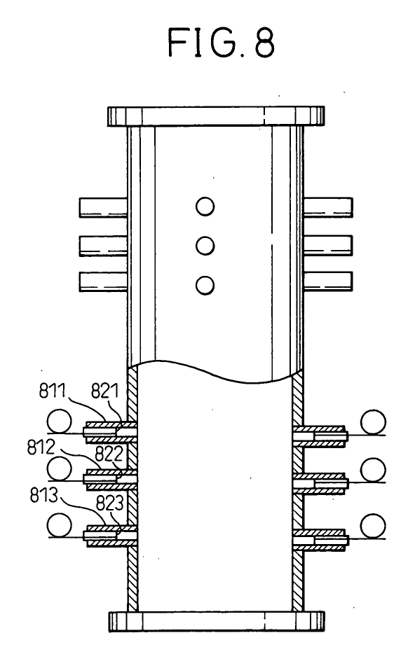

FIG. 8 is a second diagram showing the structure of a circular waveguide. The load matching device is structured using short plungers instead of the stubs.

Specifically, a circular waveguide 109 has hollow cylinders 811, 812, and 813 extended externally radially. Metallic plates 821, 822, and 823 are moved within the respective hollow cylinders 811, 812, and 813, whereby an impedance is adjusted.

The metallic plates are actuated like the stubs by using a rack and pinion and a pulse motor. Therefore, the first and second load matching device controllers can be adapted to actuate the metallic plates.

What is claimed is:

1. A plasma processing apparatus comprising:
a processing chamber;
a microwave oscillator for generating microwaves;
an antenna for radiating the microwaves to said processing chamber;
a waveguide for introducing the microwaves, which are generated by said microwave oscillator, into said antenna;
a load matching device that is disposed on said waveguide and that adjusts an impedance;
a wave detector that is disposed on said waveguide and that detects the microwaves reflected from said processing chamber; and
a controller for controlling said load matching device to match an impedance of said processing chamber, which is calculated based on the detected microwaves measurement, with an impedance of said microwave oscillator.

2. A plasma processing apparatus according to claim 1, wherein:
said controller comprises a load matching device adjustment calculation unit for calculating an amount of adjustment to which said load matching device should be adjusted in order to match the impedance of; said processing chamber with the impedance of said microwave oscillator; and an adjustment signal output unit for transmitting as an adjustment signal a calculated amount of adjustment multiplied by a predetermined value smaller than 1; and
said load matching device is repeatedly controlled until the impedance of said processing chamber matches the impedance of said microwave oscillator.

3. A plasma processing apparatus according to claim 2, wherein:
said controller further comprises a plasma detection unit that detects generation of plasma in said processing chamber;
if said plasma detection unit determines that no plasma is being generated, said adjustment signal output unit transmits an amount of adjustment, which said load matching device adjustment calculation unit has calculated, as an adjustment signal as it is;
if said plasma detection unit determines that plasma is being generated, said adjustment signal output unit transmits as an adjustment signal the amount of adjustment, which said load matching device adjustment calculation unit has calculated, multiplied by a predetermined value smaller than 1.

4. A plasma processing apparatus according to claim 2, wherein:
said controller further comprises an adjustment detection unit that detects a adjustment position by which said load matching device is adjusted;
said controller controls said load matching device according to a difference between the adjustment signal transmitted from said adjustment signal output unit and the signal of the adjustment position.

5. A plasma processing apparatus according to claim 1, wherein said load matching device has stubs.

6. A plasma processing apparatus according to claim 1, wherein said load matching device has short plungers.

7. A control method for plasma processing apparatus that utilizes plasma generated by radiating microwaves to a processing chamber, comprising the steps of:
calculating an impedance of processing chamber on the basis of the microwaves reflected from said processing chamber;
calculating an amount of adjustment, which is required in order to adjust the impedance of said processing chamber to match the calculated impedance of said processing chamber with an impedance of the microwave oscillator;
transmitting as an adjustment signal the calculated amount of adjustment multiplied by a predetermined value smaller than 1; and
repeatedly controlling the impedance of said processing chamber according to the transmitted adjustment signal until the impedance of said processing chamber matches the impedance of said microwave oscillator.

8. A control method for plasma processing apparatus according to claim 7, wherein:.
if no plasma is generated at said step of transmitting a signal, the calculated amount of adjustment is transmitted as an adjustment signal as it is; and
if plasma is generated, the calculated amount of adjustment multiplied by a predetermined value smaller than 1 is transmitted as the adjustment signal.
